(19) United States
(12) Patent Application Publication
(10) Pub. No.: US 2025/0140578 A1
(43) Pub. Date: May 1, 2025

(54) DIO3 SPRAY TANK FOR POST CMP SUBSTRATE CLEANING

(71) Applicant: Applied Materials, Inc., Santa Clara, CA (US)

(72) Inventor: Clinton P. SAKATA, Santa Clara, CA (US)

(21) Appl. No.: 18/384,810

(22) Filed: Oct. 27, 2023

(51) Int. Cl. H01L 21/67; B24B 37/34

(52) U.S. Cl. CPC H01L 21/67051; B24B 37/34

(57) ABSTRACT

Embodiments of the disclosure provided herein include an apparatus and method for processing a substrate which may be used to clean the surface of a substrate. The apparatus includes a cleaning module. The cleaning module includes a tank, a processing fluid delivery system configured to deliver a processing fluid includes ozone to the tank, a drain disposed at a bottom of the tank, and an exhaust system disposed at a top of the tank. The processing fluid delivery system includes a front side spray bar port coupled to a front side spray bar located within the tank, and a back side spray bar port coupled to a back side spray bar located within the tank opposite the front side spray bar.

### BACKGROUND

### Field

Embodiments described herein generally relate to equipment used in semiconductor manufacturing, and more particularly, to a substrate processing system which may be used to clean the surface of a substrate.

### Description of the Related Art

Substrate processing units may perform chemical mechanical polishing (CMP), which is commonly used in the manufacturing of high-density integrated circuits to planarize or polish a layer of material deposited on a substrate. Typically, after one or more CMP processes are completed, a polished substrate is further processed by use of one or more post-CMP substrate processing operations in a CMP processing system, such as by one or more cleaning operations in a cleaning unit. Various cleaning operations may be performed in a cleaning unit having multiple cleaning stations, i.e., cleaning chambers.

In cleaning units having multiple cleaning chambers, limited space is available for transferring substrates between the various chambers. Further, silicon substrate production through CMP processes generally requires additional wet bench cleaning to remove organic and inorganic particles not fully removed by typical post CMP cleaning processes. For example, a hot sulfuric-peroxide process may be used to clean substrates after polishing and cleaning through CMP systems. The impact of the additional wet bench cleaning is increased cost, facility overhead, as well as reduced yield on products.

Accordingly, there is a need for an improved apparatus and method to improve the post-CMP cleaning processes and for solving the problems described above.

### SUMMARY

Embodiments described herein generally relate to equipment used in semiconductor manufacturing, and more particularly, to a substrate processing system which may be used to clean the surface of a substrate.

In an embodiment, a substrate processing system is provided. The substrate processing system includes a polishing station, and a cleaning system that includes a substrate handler configured to transport a substrate between the polishing station and the cleaning system, a first cleaning module. The substrate processing system also includes a second cleaning module includes a tank, a processing fluid delivery system, and an exhaust system. The processing fluid delivery system is configured to deliver a processing fluid includes ozone and includes a front side spray bar port coupled to a front side spray bar located within the second cleaning module, and a back side spray bar port coupled to a back side spray bar located within the second cleaning module opposite the front side spray bar.

In another embodiment, a cleaning system is provided. The cleaning system includes a substrate handler configured to transport a substrate between a polishing station and the cleaning system, a first cleaning module, and a second cleaning module. The second cleaning module includes a tank, a processing fluid delivery system, and an exhaust system. The processing fluid delivery system is configured to deliver a processing fluid includes ozone and includes a front side spray bar port coupled to a front side spray bar located within the second cleaning module, and a back side spray bar port coupled to a back side spray bar located within the second cleaning module opposite the front side spray bar.

In yet another embodiment, a cleaning module is provided. The cleaning module includes a tank, a processing fluid delivery system configured to deliver a processing fluid includes ozone to the tank, a drain disposed at a bottom of the tank, and an exhaust system disposed at a top of the tank. The processing fluid delivery system includes a front side spray bar port coupled to a front side spray bar located within the tank, and a back side spray bar port coupled to a back side spray bar located within the tank opposite the front side spray bar.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A is a schematic top view of an exemplary chemical mechanical polishing (CMP) processing system according to one or more embodiments.

FIG. 1B is a schematic side view of the CMP processing system, according to one or more embodiments.

FIG. 2A is an isometric view of an example of a cleaning module utilized in the CMP processing system, according to one or more embodiments.

FIG. 2B is a cross-sectional view of the cleaning module of FIG. 2A, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to equipment used in the manufacturing of electronic devices, and more particularly, to a cleaning system which may be used to clean the surface of a substrate following chemical mechanical polishing (CMP) of the substrate in a semiconductor device manufacturing process.

Substrate production through CMP processes generally requires additional wet bench cleaning to remove organic and inorganic particles not fully removed by post CMP cleaning processes. For example, a hot sulfuric-peroxide process may be used to clean substrates after polishing and cleaning through CMP systems. The impact of the additional wet bench cleaning is increased cost, facility overhead, as well as reduced yield on products.

The present disclosure provides a processing fluid spray, such as an ultra-high purity water- or deionized water-ozone (DIO3) spray, onto substrate surfaces within a cleaning module to reduce organic and inorganic residues and reduce cost of ownership by extending cleaner consumables and reducing waste. The cleaning module includes a processing fluid delivery system with substrate transport hardware compatible for ozone application and an ozone exhaust system that aids in containing the ozone within the cleaning module. In particular, the ozone in the processing fluid leaves no residues on the substrate as organic particles on the substrate surface are converted to carbon dioxide exhaust. The inorganic particles are stripped by surface conversion or etched by breaking down compounds. The present disclosure requires less delivery and waste treatment resources than other chemical methods for cleaning and, as such, extends brush life, reduces the overall cost of ownership, and reduces harmful environmental waste as ozone breaks down in water or air.

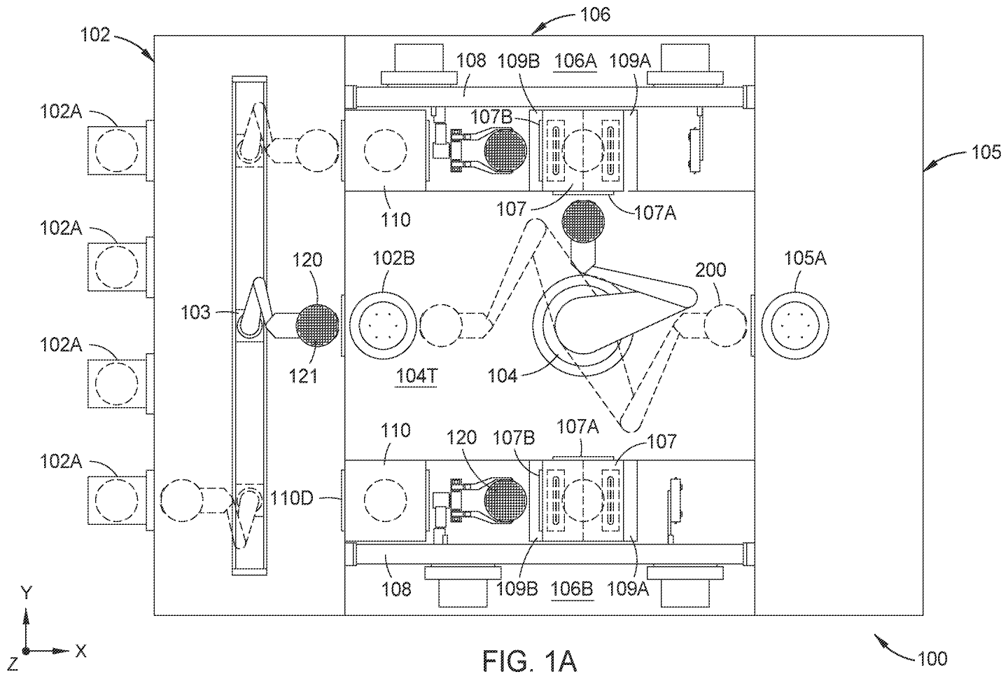

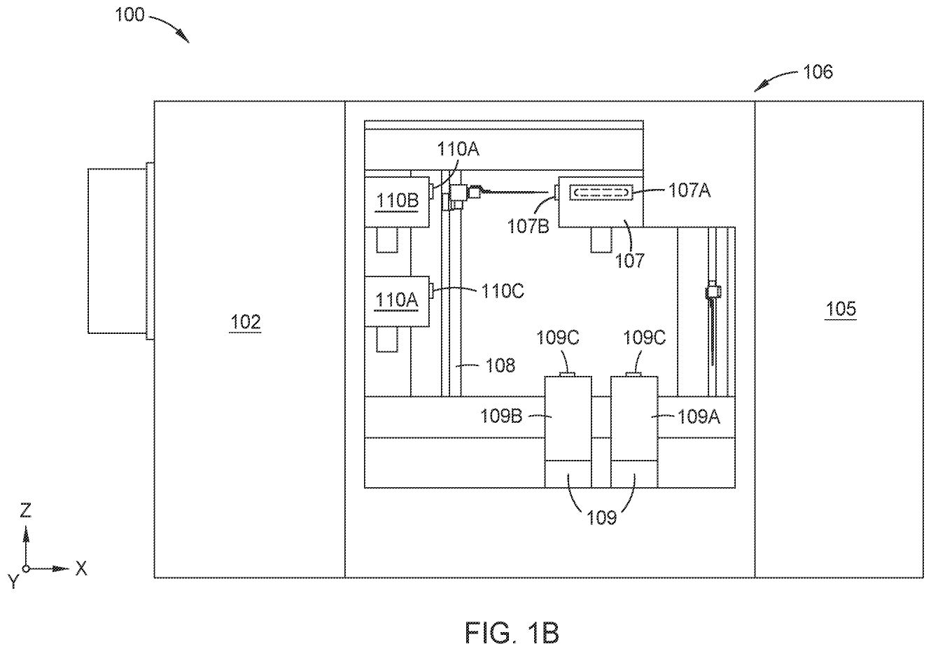

FIG. 1A is a schematic top view of an exemplary chemical mechanical polishing (CMP) processing system 100 described herein, according to one or more embodiments. FIG. 1B is a schematic side view of the CMP processing system 100, according to one or more embodiments. While the disclosure provided herein primarily discusses various embodiments that can be used in conjunction with a CMP device, such as a polishing station 105, this configuration is not intended to be limiting as to the scope of the disclosure provided herein.

In the figures, certain parts of the housing and certain other internal and external components are omitted to more clearly show aspects of the CMP processing system 100. Here, the CMP processing system 100 is connected to a factory interface 102. The factory interface 102 may include one or more loading stations 102A. The loading stations 102A may be, for example, FOUPs or cassettes. Each loading station 102A may include one or more substrates 120 for CMP processing in the CMP processing system 100.

The CMP processing system 100 may include a polishing station 105, a first substrate handler 103 of the factory interface 102 and a cleaning system 106 that includes a second substrate handler 104. The first substrate handler 103 is positioned to transfer a substrate 120 to and from one or more of the loading stations 102A. For example, the first substrate handler 103 transfers a substrate 120 from a loading station 102A to the cleaning system 106, e.g., to a cleaner pass-through 102B, where the substrate 120 can be picked up by the second substrate handler 104. As another example, the first substrate handler 103 transfers a substrate 120 from the cleaning system 106, e.g., from the cleaner pass-through 102B, to the loading station 102A.

Generally, a substrate 120 that is initially positioned in a loading station 102A has been subject to a prior manufacturing process or processes—such as, for example, lithography, etching, and/or deposition processes—on a processing surface 121 thereof. The first substrate handler 103 transfers the substrate to and from the loading station 102A with the processing surface 121 facing up.

The second substrate handler 104 may be, for example, a cleaner wet robot. The second substrate handler 104 is positioned to transfer a substrate 120 to and from the polishing station 105 with the processing surface 121 facing in an up or down orientation. For example, the second substrate handler 104 receives a substrate 120 from the cleaner pass-through 102B or the first substrate handler 103 and then transfers the substrate 120 to a transfer station 105A within the polishing station 105. As another example, the second substrate handler 104 retrieves a substrate 120 from the transfer station 105A within the polishing station 105 and then transfers the substrate 120 to a first cleaning chamber that comprises a first cleaning module 107 in the cleaning system 106. In some embodiments, the first cleaning module 107 could be replaced with a horizontal input station or vertical input station. In some embodiments, the second substrate handler 104 can include a substrate flipping capability (e.g., rotating blade wrist assembly) that allows the orientation of a substrate to be flipped from a polished surface of a substrate facing up to the polished surface of the substrate facing down orientation, or vice versa. This ability to flip the substrate during a cleaning process sequence can be useful to allow the cleaning processes performed in the cleaning system 106 to be performed on the front side of the substrate, backside of the substrate, or sequentially performed on both sides of the substrate.

The polishing station 105 is a substrate polishing system that may include a plurality of polishing stations (not shown). The polishing station 105 includes one or more polishing assemblies that are used to polish a substrate 120 received from the second substrate handler using one or more CMP processes. Typically, each of the one or more polishing assemblies includes the use of a polishing platen (not shown) and polishing head (not shown), which is configured to urge the substrate 120 against a polishing pad (not shown) disposed on the polishing platen. Residual abrasive particles and/or liquids such as acidic or basic chemicals may remain on the substrate 120 after undergoing CMP processing in the polishing station 105. Accordingly, the cleaning system 106 is positioned between the polishing station 105 and the factory interface 102 in order to clean the substrate 120 prior to returning the substrate 120 to the loading station 102A.

As shown in FIG. 1A, the cleaning system 106 may include two cleaning units 106A, 106B disposed in parallel to one another on opposite sides of the second substrate handler 104. The cleaning units 106A, 106B include a plurality of cleaning chambers. The cleaning chambers positioned within the cleaning system 106 can include one or more first cleaning modules, one or more second cleaning modules, one or more third cleaning modules, one or more fourth cleaning modules, one or more fifth cleaning modules, and/or one or more sixth cleaning modules, as discussed below. As can be appreciated from FIG. 1A and as described above, cleaning unit 106B is essentially a duplicate of the cleaning unit 106A. Accordingly, the description herein and the depiction of cleaning unit 106A in the Figures is to be understood inferentially as also a description and depiction of cleaning unit 106B.

The cleaning units 106A, 106B may be separated by a robot tunnel 104T in which the second substrate handler 104 is positioned. In some embodiments, each cleaning unit 106A, 106B includes a first cleaning module 107, a third substrate handler 108, a second cleaning module 109, and a third cleaning module 110. In some embodiments, the first cleaning module 107, while not intending to be limiting as to the scope of the disclosure provided herein is often referred to herein as the horizontal pre-clean module 107. However, as noted above, the first cleaning module 107 could be replaced by a vertical input station or a horizontal input station that are each generally configured to support a substrate in a desired physical orientation while assuring that the surfaces of the substrate remain wet prior to subsequent cleaning processes being performed thereon. In some embodiments, the second cleaning module 109, while not intending to be limiting as to the scope of the disclosure provided herein is often referred to herein as the vertical cleaning module 109. In some embodiments, the third cleaning module 110, while not intending to be limiting as to the scope of the disclosure provided herein, is often referred to herein as the integrated clean and dry (ICD) module 110. In some embodiments, the vertical cleaning module 109 may be provided as a first vertical cleaning module 109A and a second vertical cleaning module 109B, each of which having a door 109C. In some embodiments, the integrated clean and dry module 110 may be provided as a first integrated clean and dry module 110A and a second integrated clean and dry module 110B. In some embodiments, as illustrate in FIG. 1A, the third substrate handler 108 within each of the cleaning unit 106A, 106B is positioned such that it is at an external edge of the cleaning unit 106A, 106B of the CMP processing system 100. In this configuration, the substrate handler 108 is positioned on an external side of the cleaning chambers, such as the first, second, and third cleaning modules as shown, which is opposite to an internal side of the first, second, and third cleaning modules that faces the robot tunnel 104T and the second substrate handler 104 of the CMP processing system 100.

The horizontal pre-clean module 107 is configured to process a substrate 120 disposed in a substantially horizontal orientation, i.e., in the X-Y plane, with the processing surface 121 facing up. In some embodiments, each cleaning unit 106A, 106B includes two vertical cleaning modules 109A, 109B configured to process a substrate 120 disposed in a substantially vertical orientation, i.e., in the Z-Y plane, with the processing surface 121 facing the factory interface 102.

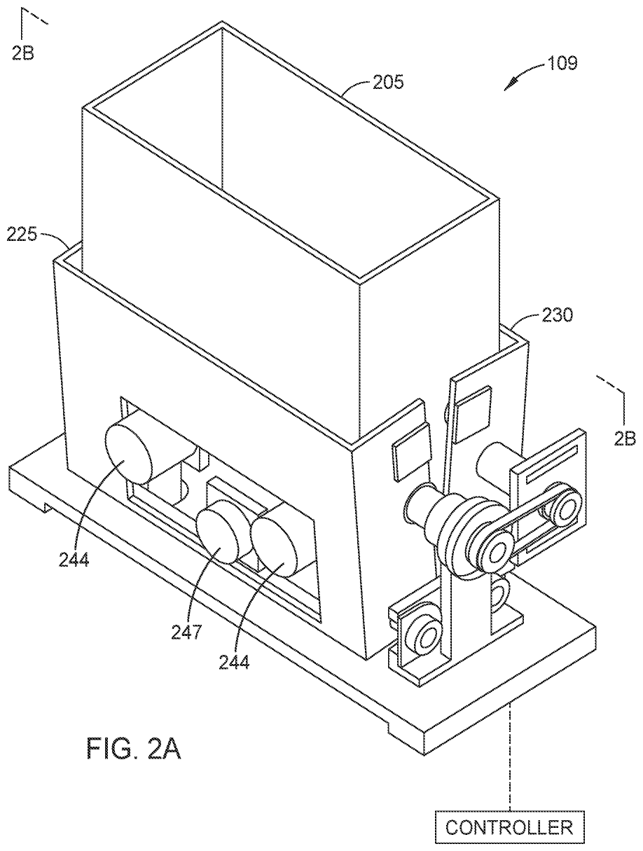

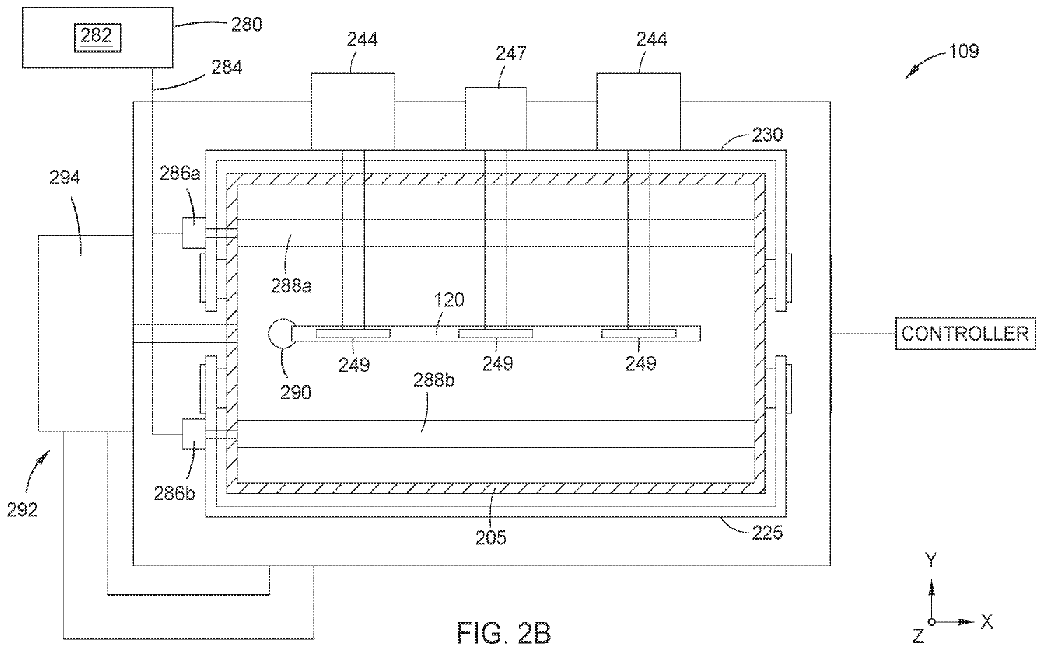

FIG. 2A is an isometric view of an example vertical cleaning module 109 that is representative of the vertical cleaning modules 109A, 109B and that may be utilized in a cleaning unit as described above. The lid portion of the vertical cleaning module 109, which includes the door 109C, has been removed from FIGS. 2A and 2B for ease of discussion. The example vertical cleaning module 109 includes a tank 205 that is supported by a first support 225 and a second support 230.

FIG. 2B is a top view of the vertical cleaning module 109 in FIG. 2A in a processing position. The vertical cleaning module 109 also includes one or more drive motors 244 and a rotational device 247. Each of the drive motors 244 and the rotational device 247 include a roller 249, which is disposed at the end of an output shaft of each drive motor 244 and rotational device 247 and are configured to support and/or engage the substrate 120 and facilitate rotation of the substrate 120 about an axis that is parallel to the horizontal plane (i.e., X-Y plane).

A processing fluid, is applied to the surface of the substrate 120 from a fluid source while the substrate 120 is rotated by the various actuators and motors. In some embodiments, the processing fluid is applied to the substrate 120 by a processing fluid delivery system 280. The processing fluid is a solution that contains ozone mixed into ultra-high purity water, e.g., DI water, prior to delivery to the cleaning module 109. As such, all of the internal components of the vertical cleaning module 109 should be made of ozone-compatible materials, such as chlorinated polyvinyl chloride (CPVC), polyvinylidene fluoride (PVDF), ethylene chlorotrifluoroethylene (ECTFE), polyfluoroalkyl (PFA), polytetrafluoroethylene (PTFE), polyether ether ketone (PEEK), fluorine kautschuk material (FKM), polychlorotrifluoroethylene (PCTFE), polyvinyl chloride (PVC), or a combination thereof. The flow of the processing fluid is controlled by a flow and pressure regulator 282, such that the processing fluid is flowed at about 0.5 liters per minute (LPM) to about 3 LPM, such as about 1 LPM to about 2 LPM, sourced from a chemical delivery cabinet or liquid delivery module (not shown). The flow is delivered to the cleaning module 109 via conduits 284. The conduits 284 may include tubing made of materials that are compatible with ozone, such as perfluoroalkoxy (PFA) tubing, double contained to both a front side spray bar port 286a and a back side spray bar port 286b disposed on the first support 225 of the cleaning module 109. The cleaning module 109 accepts a single substrate through its door lid 109C (FIG. 1B) which may be pneumatically controlled as a robot arm transfers the substrate 120 to the cleaning module 109. After the robot arm is removed from cleaning module 109, the door lid closes, and the substrate 120 rotates at about 1 rotation per minute (rpm) to about 75 rpm, such as about 4 rpm to about 50 rpm.

The processing fluid delivery system 280 further includes spray bars, e.g., a front side spray bar 288a disposed within the tank 205 and a back side spray bar 288b disposed within the tank 205 opposite the front side spray bar 288a, that rinse the substrate 120 with the processing fluid as the substrate 120 rotates to cover both sides, the front side and the back side, of the substrate 120. The resulting waste is collected in a drain port 290 disposed at the bottom of the cleaning module 109 and ozone exhaust is ported from an ozone exhaust system 292 disposed at the top of the cleaning module 109 to prevent ozone from escaping outside the cleaning module 109. The exhaust system includes an exhaust separator 294 that is configured to recapture ozone from the exhaust and reflow the ozone into the tank 205.

Incorporating the processing fluid with ozone using the cleaning module 109 requires less delivery and waste treatment resources than other chemical methods for cleaning. This further leads to improvement in cleaning and extends brush life, reducing the overall cost of ownership and harmful environmental waste as ozone breaks down in water or air.

During cleaning processing in each vertical cleaning module 109A, 109B, the substrate 120 may be positioned so that the processing surface 121 faces the factory interface 102. In another embodiment, the vertical cleaning modules 109A and 109B are oriented within the cleaning units 106A, 106B so that the processing surface 121 during a cleaning process faces an orientation that is substantially perpendicular to the factory interface 102 (e.g., parallel to the X-Z plane). In another embodiment, the vertical cleaning modules 109A and 109B are oriented within the cleaning units 106A, 106B so that the processing surface 121 of the substrate 120 during a cleaning process face an orientation that is at an angle between parallel to the X-Z plane and parallel to Y-Z plane.

The present disclosure provides for a cleaning system for a CMP processing system that includes a cleaning module that delivers a processing fluid containing ozone (O₃) while brushing a substrate. Incorporating the processing fluid with ozone requires less delivery and waste treatment resources than other chemical methods for cleaning. This further leads to improvement in cleaning and extends brush life for subsequent brush cleaning process downstream, reducing the overall cost of ownership and harmful environmental waste as ozone breaks down in water or air.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a polishing station; and
a cleaning system comprising:
a substrate handler configured to transport a substrate between the polishing station and the cleaning system;
a first cleaning module; and
a second cleaning module comprising a tank, a processing fluid delivery system, and an exhaust system, the processing fluid delivery system configured to deliver a processing fluid comprising ozone.

2. The substrate processing system of claim 1, wherein the exhaust system is disposed at a top of the tank.

3. The substrate processing system of claim 1, wherein the processing fluid delivery system comprises:
a front side spray bar port coupled to a front side spray bar located within the second cleaning module; and
a back side spray bar port coupled to a back side spray bar located within the second cleaning module opposite the front side spray bar.

4. The substrate processing system of claim 3, wherein the front side spray bar and the back side spray bar are configured to rinse a front side and a back side of a substrate with the processing fluid.

5. The substrate processing system of claim 1, wherein the processing fluid further comprises water.

6. The substrate processing system of claim 1, wherein the processing fluid is flowed to the second cleaning module at about 0.5 liters per minute to 3 liters per minute.

7. The substrate processing system of claim 1, wherein the exhaust system is disposed at a top of the second cleaning module and configured to exhaust ozone from waste produced by the processing fluid.

8. A cleaning system, comprising:
a substrate handler configured to transport a substrate between a polishing station and the cleaning system;
a first cleaning module; and
a second cleaning module comprising a tank, a processing fluid delivery system, and an exhaust system, the processing fluid delivery system configured to deliver a processing fluid comprising ozone.

9. The cleaning system of claim 8, wherein the exhaust system is disposed at a top of the tank.

10. The cleaning system of claim 8, wherein the processing fluid delivery system comprises:
a front side spray bar port coupled to a front side spray bar located within the second cleaning module; and
a back side spray bar port coupled to a back side spray bar located within the second cleaning module opposite the front side spray bar.

11. The cleaning system of claim 10, wherein the front side spray bar and the back side spray bar are configured to rinse a front side and a back side of a substrate with the processing fluid.

12. The cleaning system of claim 8, wherein the processing fluid further comprises water.

13. The cleaning system of claim 8, wherein the processing fluid is flowed to the second cleaning module at about 0.5 liters per minute to 3 liters per minute.

14. The cleaning system of claim 8, wherein the exhaust system is disposed at a top of the second cleaning module and configured to exhaust ozone from waste produced by the processing fluid.

15. A cleaning module, comprising:
a tank;
a processing fluid delivery system configured to deliver a processing fluid comprising ozone to the tank;
a drain disposed at a bottom of the tank; and
an exhaust system disposed at a top of the tank.

16. The cleaning module of claim 15, wherein the processing fluid delivery system comprises:
a front side spray bar port coupled to a front side spray bar located within the tank; and
a back side spray bar port coupled to a back side spray bar located within the tank opposite the front side spray bar.

17. The cleaning module of claim 16, wherein the front side spray bar and the back side spray bar are configured to rinse a front side and a back side of a substrate with the processing fluid.

18. The cleaning module of claim 15, wherein the processing fluid further comprises water.

19. The cleaning module of claim 15, wherein the processing fluid is flowed to the cleaning module at about 0.5 liters per minute to 3 liters per minute.

20. The cleaning module of claim 15, wherein the exhaust system is configured to exhaust ozone from waste produced by the processing fluid.
